(19) United States
(12) Patent Application Publication
(10) Pub. No.: US 2024/0421232 A1
(43) Pub. Date: Dec. 19, 2024

(54) SEMICONDUCTOR DEVICE

(71) Applicant: SAMSUNG ELECTRONICS CO., LTD., Suwon-si (KR)

(72) Inventors: Suk YANG, Suwon-si (KR); Sung-Hwan JANG, Suwon-si (KR); Do Hee KIM, Suwon-si (KR); Jin Bum KIM, Suwon-si (KR); Sung Uk JANG, Suwon-si (KR); Inhae ZOH, Suwon-si (KR)

(21) Appl. No.: 18/586,125

(22) Filed: Feb. 23, 2024

(30) Foreign Application Priority Data
Jun. 15, 2023 (KR) 10-2023-0076950

(51) Int. Cl. H01L 29/786; H01L 29/06; H01L 29/423; H01L 29/66; H01L 29/78

(52) U.S. Cl. CPC H01L 29/78696; H01L 29/0603; H01L 29/42392; H01L 29/785; H01L 29/66545

(57) ABSTRACT

A semiconductor device includes a lower pattern extending in a first direction, a plurality of wire patterns spaced apart from the lower pattern in a second direction on the lower pattern, and a gate electrode surrounding the plurality of wire patterns and extending in a third direction, on the lower pattern. Each of the plurality of wire patterns includes a transition metal dichalcogenide (TMD) material. Each of the plurality of wire patterns includes a pair of first areas protruding from sidewalls of the gate electrode in the first direction and a second area between the first areas. A phase of the first area is different from a phase of the second area.

### CROSS-REFERENCE TO RELATED APPLICATION

This application claims priority to Korean Patent Application No. 10-2023-0076950 filed on Jun. 15, 2023 in the Korean Intellectual Property Office, and all the benefits accruing therefrom under 35 U.S.C. § 119, the content of which in its entirety is herein incorporated by reference.

### BACKGROUND

As one of the scaling techniques for increasing a density of semiconductor devices, a multi-gate transistor in which a multi-channel active pattern (or silicon body) having a fin or nanowire shape is formed on a substrate and a gate is formed on a surface of the multi-channel active pattern has been proposed.

Since such a multi-gate transistor uses a three-dimensional channel, it is easy to perform scaling. In addition, it is possible to improve current control capability even without increasing a length of the gate of the multi-gate transistor. In addition, it is possible to effectively suppress a short channel effect (SCE) in which a potential of a channel region is affected by a drain voltage.

Meanwhile, as a pitch size of the semiconductor device decreases, research for reducing capacitance and securing electrical stability between contacts in the semiconductor device is required.

### SUMMARY

Aspects of the present disclosure provide a semiconductor device capable of having improved performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor device comprising, a lower pattern extending in a first direction, a plurality of wire patterns spaced apart from the lower pattern in a second direction on the lower pattern, and a gate electrode surrounding the plurality of wire patterns and extending in a third direction, on the lower pattern, wherein each of the plurality of wire patterns includes a transition metal dichalcogenide (TMD) material, wherein each of the plurality of wire patterns includes a pair of first areas protruding from sidewalls of the gate electrode in the first direction and a second area between the first areas, and wherein a phase of the first area is different from a phase of the second area.

According to another aspect of the present disclosure, there is provided a semiconductor device comprising, a lower pattern extending in a first direction, a plurality of wire patterns spaced apart from the lower pattern in a second direction on the lower pattern, a plurality of gate electrodes surrounding the plurality of wire patterns, extending in a third direction, and spaced apart from each other in the first direction, on the lower pattern, and a source/drain pattern connected to the plurality of wire patterns between the plurality of gate electrodes adjacent to each other, wherein each of the plurality of wire patterns includes a transition metal dichalcogenide (TMD) material, wherein each of the plurality of wire patterns includes a first area surrounded by the source/drain pattern and a second area that is not in contact with the source/drain pattern, wherein a molecular structure of the first area has a first angle between a transition metal and chalcogen elements adjacent to each other in plan view, wherein a molecular structure of the second area has a second angle between a transition metal and chalcogen elements adjacent to each other in plan view, and wherein the first angle is less than the second angle.

According to another aspect of the present disclosure, there is provided a semiconductor device comprising, a lower pattern extending in a first direction, a plurality of wire patterns spaced apart from the lower pattern in a second direction on the lower pattern and each including a pair of first areas spaced apart from each other in the first direction and a second area between the first areas, a plurality of gate electrodes surrounding second areas of the plurality of wire patterns, extending in a third direction, and spaced apart from each other in the first direction, on the lower pattern, a source/drain pattern connected to the plurality of wire patterns between the plurality of gate electrodes adjacent to each other, and a barrier pattern interposed between the first area and the source/drain pattern, wherein each of the plurality of wire patterns includes a transition metal dichalcogenide (TMD) material, and wherein a transition metal included in the barrier pattern is a Group 4 transition metal.

### BRIEF DESCRIPTION OF THE DRAWINGS

The above and other aspects and features of the present disclosure will become more apparent by describing in detail implementations thereof with reference to the attached drawings, in which:

FIG. 1 is an exemplary plan view for describing a semiconductor device according to some implementations.

FIG. 2 is an exemplary cross-sectional view taken along line A-A of FIG. 1.

FIG. 3 is an enlarged view of area P of FIG. 2.

FIG. 4 is an exemplary cross-sectional view taken along line B-B of FIG. 1.

FIG. 5 is an exemplary perspective view for describing a wire pattern of FIG. 1.

FIG. 6 is a plan view for describing a molecular structure of a first area of the wire pattern of FIG. 5.

FIG. 7 is a plan view for describing a molecular structure of a second area of the wire pattern of FIG. 5.

FIGS. 8 to 12 are views for describing a semiconductor device according to some other implementations.

FIG. 13 is a view for describing a semiconductor device according to some still other implementations.

FIG. 14 is an enlarged view of area S of FIG. 13.

FIGS. 15 and 16 are views for describing a semiconductor device according to some still other implementations.

FIGS. 17 to 23 are intermediate step views for describing a method of manufacturing a semiconductor device having the cross section of FIG. 2.

FIGS. 24 to 27 are intermediate step views for describing a method of manufacturing a semiconductor device having the cross section of FIG. 13.

### DETAILED DESCRIPTION OF THE EMBODIMENTS

Terms “first”, “second” and the like are used herein to describe various elements or components, but these elements or components are not limited by these terms. These terms are used only to distinguish one element or component from another element or component. Therefore, a first element or component mentioned below may be a second element or component within the technical spirit of the present disclosure.

In the drawings of a semiconductor device according to some implementations, a fin-type transistor (FinFET) including a channel region having a fin-type pattern shape, a transistor including nanowires or nanosheets, a multi-bridge channel field effect transistor (MBCFET), or vertical FET is exemplarily illustrated, but the present disclosure is not limited thereto. The semiconductor device according to some implementations may include a tunneling FET or a three-dimensional (3D) transistor. The semiconductor device according to some implementations may include a planar transistor. In addition, some features of the present disclosure may be applied to two-dimensional (2D) material based FETs and a heterostructure thereof.

In addition, the semiconductor device according to some implementations may also include a bipolar junction transistor, a lateral double-diffused metal oxide semiconductor (LDMOS) transistor, or the like.

Hereinafter, implementations of the present disclosure will be described with reference to the accompanying drawings.

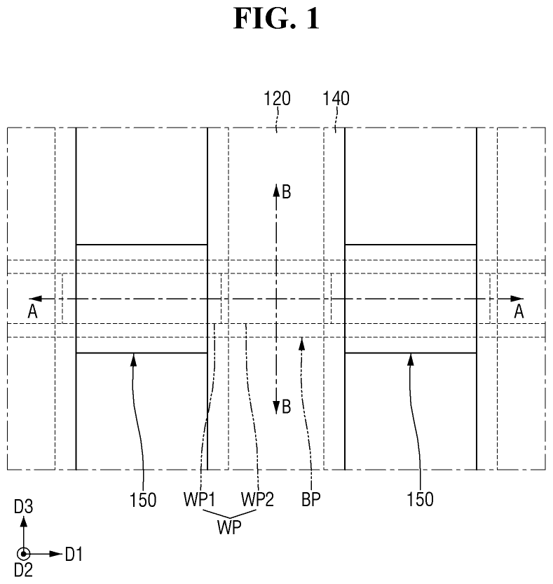

A semiconductor device according to some implementations will be described with reference to FIGS. 1 to 7.

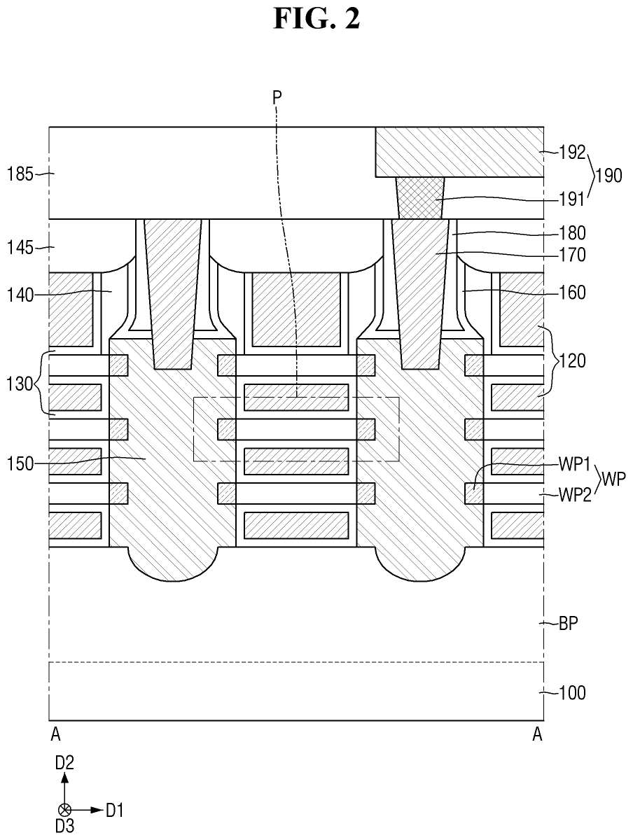

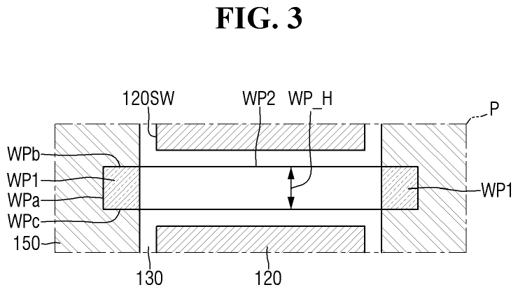

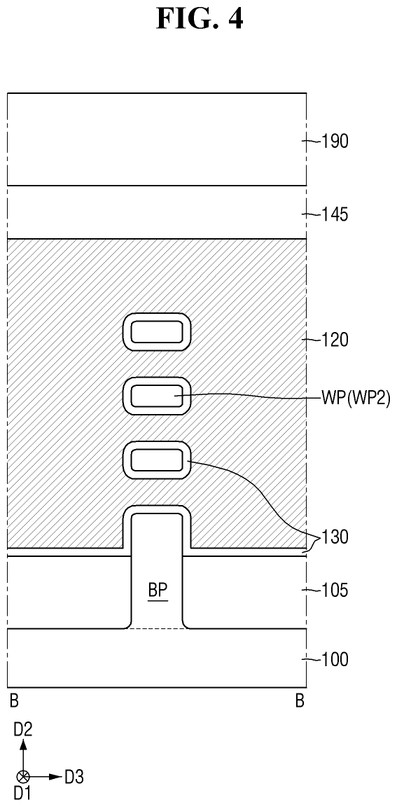

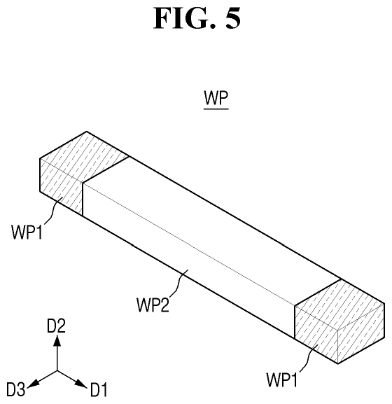

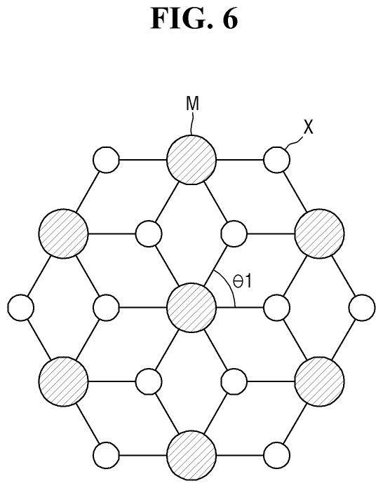

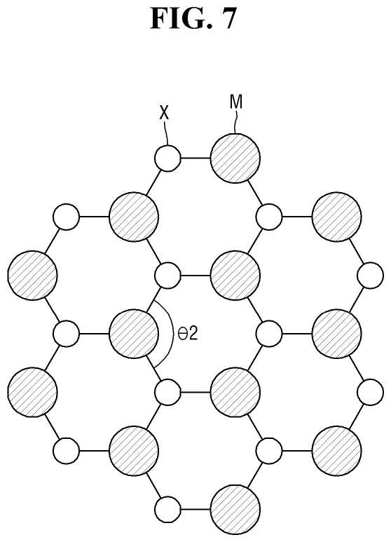

FIG. 1 is an exemplary plan view for describing a semiconductor device according to some implementations. FIG. 2 is an exemplary cross-sectional view taken along line A-A of FIG. 1. FIG. 3 is an enlarged view of area P of FIG. 2. FIG. 4 is an exemplary cross-sectional view taken along line B-B of FIG. 1. FIG. 5 is an exemplary perspective view for describing a wire pattern of FIG. 1. FIG. 6 is a plan view for describing a molecular structure of a first area of the wire pattern of FIG. 5. FIG. 7 is a plan view for describing a molecular structure of a second area of the wire pattern of FIG. 5.

Referring to FIGS. 1 to 7, a semiconductor device according to some implementations includes a lower pattern BP, a plurality of wire patterns WP, a plurality of gate electrodes 120, and a source/drain pattern 150.

A substrate 100 may be provided. The substrate 100 may be bulk silicon or silicon-on-insulator (SOI). Alternatively, the substrate 100 may be a silicon substrate, and may include another material, for example, silicon germanium, silicon germanium on insulator (SGOI), indium antimonide, lead tellurium compound, indium arsenide, indium phosphide, gallium arsenide, or gallium antimonide, but is not limited thereto.

The lower pattern BP may be disposed on the substrate 100. The lower pattern BP may extend in a first direction DI. The lower pattern BP may protrude from the substrate 100 in a second direction D2. The lower pattern BP may be a fin-shaped pattern. The first direction DI and the second direction D2 may intersect each other. The first direction DI and the second direction D2 may be substantially perpendicular to each other. In addition, a third direction D3 may intersect the first direction D1 and the second direction D2. The first to third directions D1, D2, and D3 may be substantially perpendicular to each other.

A plurality of wire patterns WP may be disposed on the lower pattern BP. The plurality of wire patterns WP may be spaced apart from an upper surface of the lower pattern BP in the second direction D2. Each of the plurality of wire patterns WP may be spaced apart from each other in the second direction D2. The plurality of wire patterns WP may be connected to a source/drain pattern 150 to be described later. It is illustrated that three wire patterns WP are disposed in the second direction D2, but this is only for convenience of explanation, and the present disclosure is not limited thereto.

The lower pattern BP may also be formed by etching a portion of the substrate 100 and may include an epitaxial layer grown from the substrate 100. The lower pattern BP may include silicon or germanium, which is an elemental semiconductor material. In addition, the lower pattern BP may include a compound semiconductor, for example, a group IV-IV compound semiconductor or a group III-V compound semiconductor.

The group IV-IV compound semiconductor may be, for example, a binary compound or a ternary compound including at least two or more of carbon (C), silicon (Si), germanium (Ge), and tin (Sn), or a compound obtained by doping carbon (C), silicon (Si), germanium (Ge), and tin (Sn) with a group IV element.

The group III-V compound semiconductor may be, for example, one of a binary compound, a ternary compound, or a quaternary compound formed by combining at least one of aluminum (Al), gallium (Ga), and indium (In), which are group III elements, with one of phosphorus (P), arsenic (As), and antimony (Sb), which are group V elements.

Each of the wire patterns WP may include a two-dimensional (2D) material layer. For example, each of the wire patterns WP may include a transition metal dichalcogenide (TMD) material. For example, the TMD material may have the form of MX₂. The M may be a transition metal, and the X may be a chalcogen clement. That is, the TMD material may be a combination of one transition metal and two chalcogen elements.

The transition metal may include scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), ruthenium (Ru), rhodium (Rh), palladium (Pd), cadmium (Cd), hafnium (Hf), tantalum (Ta), tungsten (W), and iridium (Ir). The chalcogen element may include sulfur(S), selenium (Se), and tellurium (Te).

As an example, the wire patterns WP may include at least one of WS₂, WSe₂, WTe₂, ZrS₂, ZrSe₂, ZrTe₂, MoS₂, MoSe₂, and MoTe₂, but are not limited thereto.

In the semiconductor device according to some implementations, the lower pattern BP may be a silicon lower pattern including silicon, and the wire pattern WP may be a TMD wire pattern including the transition metal dichalcogenide material (TMD material). A thickness WP_H of the wire pattern WP in the second direction D2 may be very thin. For example, the thickness WP_H of the wire pattern WP in the second direction D2 may be 1 nm or less, but the technical spirit of the present disclosure is not limited thereto. Since the semiconductor device has a structure in which the wire pattern WP has a thickness of 1 nm or less, a scaled semiconductor device may be manufactured.

In some implementations, each of the wire patterns WP includes a pair of first areas WP1 and include a second area WP2.

The wire patterns WP may extend in the first direction D1. That is, a length of the wire pattern WP in the first direction D1 may be greater than a length thereof in the second direction D2.

The pair of first areas WP1 may be spaced apart from each other in the first direction D1. The second area WP2 may be disposed between the pair of first areas WP1. The pair of first areas WP1 may protrude from a sidewall 120SW of a gate electrode 120 to be described later. The pair of first areas WP1 may also protrude from a sidewall of a gate insulating film 130.

The pair of first areas WP1 may be surrounded by the source/drain pattern 150. At least a portion of the pair of first areas WP1 may be disposed within the source/drain pattern 150. As an example, all of the pair of first areas WP1 may be disposed within the source/drain pattern 150. As another example, at least a portion of the pair of first areas WP1 may not be disposed within the source/drain pattern 150. The pair of first areas WP1 may be in contact with the source/drain pattern 150.

The second area WP2 may be surrounded by the gate electrode 120. The second area WP2 may be surrounded by the gate insulating film 130. The second area WP2 may not be in contact with the source/drain pattern 150.

In some implementations, a phase of the first areas WP1 and a phase of the second area WP2 may be different from each other. For example, the phase of the first areas WP1 may be a 1T phase, and the phase of the second area WP2 may be a 2H phase. However, the technical spirit of the present disclosure is not limited thereto.

In some implementations, a resistance between a TMD material having a 1T phase and a metal may be about 0.48 kΩ. A resistance between a TMD material having a 2T phase and a metal may be about 2.2 kΩ. Since each of the first areas WP1 has the 1T phase, a resistance may be reduced at a contact portion between the first areas WP1 and the source/drain pattern 150 containing a semimetal. Accordingly, a semiconductor device having improved performance may be manufactured.

In some implementations, a molecular structure of the first areas WP1 and a molecular structure of the second area WP2 may be different from each other in plan view. This may be because the phase of the first areas WP1 and the phase of the second area WP2 are different from each other.

For example, in FIG. 6, in the molecular structure of the first areas WP1 in plan view, six chalcogen elements X may be disposed around one transition metal M. Three transition metals M may be disposed around one chalcogen element X. In addition, in plan view, the molecular structure of the first areas WP1 has a first angle θ1 between the transition metal M and two chalcogen elements X closest to each other. The first angle θ1 may be about 60°, but the technical spirit of the present disclosure is not limited thereto.

In the present specification, the meaning of “the two chalcogen elements closest to each other” may mean “two chalcogen elements having the shortest distance among the distances between the two chalcogen elements”.

In FIG. 7, in the molecular structure of the second area WP2 in plan view, six chalcogen elements X may be disposed around one transition metal M. In addition, in plan view, the molecular structure of the second area WP2 has a second angle θ2 between the transition metal M and two chalcogen elements X closest to each other. The second angle θ2 may be about 120°, but the technical spirit of the present disclosure is not limited thereto.

In some implementations, the first angle θ1 may be smaller than the second angle θ2. That is, in plan view, the transition metals M and the chalcogen elements X of the first areas WP1 may be more densely disposed than the transition metals M and the chalcogen elements X of the second area WP2. Accordingly, the first areas WP1 may have higher metallic properties than the second area WP2.

In FIG. 3, in a cross-sectional view, each of the first areas WP1 may include a first surface WPa, a second surface WPb, and a third surface WPc. The first surface WPa may be opposite to the second area WP2. The second surface WPb may be opposite to the substrate 100. The third surface WPc may face the substrate 100. The first surface WPa, the second surface WPb, and the third surface WPc may be all in contact with the source/drain pattern 150. As each of the first areas WP1 of the wire pattern WP protrudes from the sidewall 120SW of the gate electrode 120, an area of a contact portion where the source/drain pattern 150 and the wire pattern WP are in contact with each other may be increased. Accordingly, a resistance between the wire pattern WP and the source/drain pattern 150 may be reduced.

A field insulating film 105 may be formed on the substrate 100. The field insulating film 105 may cover a sidewall of the lower pattern BP. The wire patterns WP are disposed to be higher than an upper surface of the field insulating film 105. The wire patterns WP may be spaced apart from the upper surface of the field insulating film 105 in the second direction D2.

The field insulating film 105 may include, for example, an oxide film, a nitride film, an oxynitride film, or a combination thereof. The field insulating film 105 is illustrated as a single film, but is not limited thereto. Alternatively, the field insulating film 105 may also include a field liner extending along a sidewall and a bottom surface of a fin trench defining the lower pattern BP and a field filling film on the field liner.

A plurality of gate electrodes 120 may be disposed on the lower pattern BP. The plurality of gate electrodes 120 may intersect the lower pattern BP. The plurality of gate electrodes 120 may surround the wire pattern WP.

The gate electrode 120 may include at least one of a metal, a metal alloy, conductive metal nitride, metal silicide, a doped semiconductor material, conductive metal oxide, and conductive metal oxynitride. The gate electrode 120 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and combinations thereof, but is not limited thereto. The conductive metal oxide and the conductive metal oxynitride may include an oxidized form of the above-described materials, but are not limited thereto.

The gate electrodes 120 may be disposed on both sides of the source/drain pattern 150. As an example, all of the gate electrodes 120 disposed on both sides of the source/drain pattern 150 may be normal gate electrodes used as gates of the transistor. As another example, the gate electrode 120 disposed on one side of the source/drain pattern 150 is used as the gate of the transistor, but the gate electrode 120 disposed on the other side of the source/drain pattern 150 may be a dummy gate electrode.

A plurality of gate spacers 140 may be disposed on sidewalls of the plurality of gate electrodes 120. The plurality of gate spacers 140 are not in contact with the plurality of gate electrodes 120. The gate insulating film 130 may be disposed between the gate spacer 140 and the sidewall of the gate electrode 120. Each of the plurality of gate spacers 140 may extend in the third direction D3. In FIG. 2, a width of the gate spacer 140 may decrease from a gate capping film 145 toward the wire pattern WP. This may be because a portion of the gate spacer 140 is removed in a process of forming the first areas WP1 of the wire pattern WP.

The plurality of gate spacers 140 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof.

The gate insulating film 130 may extend between the gate electrodes 120 and the upper surface of the field insulating film 105, between the gate electrodes 120 and the upper surface of the lower pattern BP, and between the gate electrodes 120 and the wire patterns WP. The gate insulating film 130 may be formed between the gate electrodes 120 and the gate spacers 140. In addition, the gate insulating film 130 may also be formed between the source/drain pattern 150 and the gate electrodes 120.

The gate insulating film 130 may include silicon oxide, silicon oxynitride, silicon nitride, or a high-k material having a dielectric constant greater than that of the silicon oxide. The high-k material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

Although the gate insulating film 130 is illustrated as a single film, this is merely for convenience of explanation, and the present disclosure is not limited thereto. The gate insulating film 130 may include a plurality of films.

The semiconductor device according to some implementations may include a negative capacitance (NC) FET using a negative capacitor. For example, the gate insulating film 130 may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series with each other and the capacitance of each capacitor has a positive value, a total capacitance decreases as compared with a capacitance of each individual capacitor. On the other hand, when at least one of the capacitances of two or more capacitors connected in series with each other has a negative value, the total capacitance may be greater than an absolute value of each individual capacitance while having a positive value.

When the ferroelectric material film having the negative capacitance and the paraelectric material film having the positive capacitance are connected in series with each other, a total capacitance value of the ferroelectric material film and the paraelectric material film connected in series with each other may increase. A transistor including the ferroelectric material film may have a subthreshold swing (SS) less than 60 mV/decade at room temperature by using the increase in the total capacitance value.

The ferroelectric material film may have the ferroelectric characteristics. The ferroelectric material film may include, for example, at least one of hafnium oxide, hafnium zirconium oxide, barium strontium titanium oxide, barium titanium oxide, and lead zirconium titanium oxide. Here, as an example, the hafnium zirconium oxide may be a material obtained by doping hafnium oxide with zirconium (Zr). As another example, the hafnium zirconium oxide may also be a compound of hafnium (Hf), zirconium (Zr), and oxygen (O).

The ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of dopant included in the ferroelectric material film may vary depending on a type of ferroelectric material included in the ferroelectric material film.

When the ferroelectric material film includes hafnium oxide, the dopant included in the ferroelectric material film may include, for example, at least one of gadolinium (Gd), silicon (Si), zirconium (Zr), aluminum (Al), and yttrium (Y).

When the dopant is aluminum (Al), the ferroelectric material film may include 3 to 8 atomic % (at %) of aluminum. Here, a ratio of the dopant may be a ratio of aluminum to the sum of hafnium and aluminum.

When the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may contain 1 to 7 at % of gadolinium. When the dopant is zirconium (Zr), the ferroelectric material film may include 50 to 80 at % of zirconium.

The paraelectric material film may have the paraelectric characteristics. The paraelectric material film may include, for example, at least one of silicon oxide and metal oxide having a high dielectric constant. The metal oxide included in the paraelectric material film may include, for example, at least one of hafnium oxide, zirconium oxide, and aluminum oxide, but is not limited thereto.

The ferroelectric material film and the paraelectric material film may include the same material. The ferroelectric material film may have the ferroelectric characteristics, but the paraelectric material film may not have the ferroelectric characteristics. For example, when the ferroelectric material film and the paraelectric material film include the hafnium oxide, a crystal structure of the hafnium oxide included in the ferroelectric material film is different from a crystal structure of the hafnium oxide included in the paraelectric material film.

The ferroelectric material film may have a thickness having the ferroelectric characteristics. The thickness of the ferroelectric material film may be, for example, 0.5 to 10 nm, but is not limited thereto. Since a critical thickness representing the ferroelectric characteristics may vary for each ferroelectric material, the thickness of the ferroelectric material film may vary depending on the ferroelectric material.

The plurality of gate capping films 145 may be disposed on upper surfaces of the plurality of gate electrodes 120 and upper surfaces of the plurality of gate spacers 140, respectively. The plurality of gate capping films 145 may include, for example, at least one of silicon nitride (SiN), silicon oxynitride (SiON), silicon oxide (SiO₂), silicon carbonitride (SiCN), silicon oxycarbonitride (SiOCN), and a combination thereof.

The source/drain pattern 150 may be disposed on the substrate 100. The source/drain pattern 150 may be formed on the lower pattern BP. The source/drain pattern 150 is connected to the lower pattern BP. A bottom surface of the source/drain pattern 150 is connected to the lower pattern BP. The source/drain pattern 150 may also be connected to the plurality of wire patterns WP. The source/drain pattern 150 may be in contact with the first areas WP1 of the wire pattern WP.

The source/drain pattern 150 may be disposed on a side surface of each of the plurality of gate electrodes 120. The source/drain pattern 150 may be disposed between the gate electrodes 120 adjacent to each other.

For example, the source/drain pattern 150 may be disposed on both sides of the plurality of gate electrodes 120. Unlike illustrated, the source/drain pattern 150 may be disposed on one side of the plurality of gate electrodes 120 and may not be disposed on the other side of the plurality of gate electrodes 120.

As an example, the source/drain pattern 150 may include a semimetal material. The semimetal material may include bismuth (Bi), arsenic (As), and antimony (Sb), but is not limited thereto. The source/drain pattern 150 may be included in a source/drain of a transistor using the wire pattern WP as a channel region. The source/drain pattern 150 may be a single layer. As another example, the source/drain pattern 150 may include a metal material. Hereinafter, the source/drain pattern 150 will be described as including a semimetal material.

An etching stop film 160 may extend along the upper surface of the field insulating film 105, the sidewalls of the plurality of gate spacers 140, and a profile of the source/drain pattern 150. The etching stop film 160 may be disposed on the upper surface of the source/drain pattern 150, the sidewall of the source/drain pattern 150, and the sidewalls of the plurality of gate spacers 140. In some implementations, the etching stop film 160 is not disposed on the sidewall of the gate capping film 145. That is, the gate capping film 145 may be disposed on an upper surface of the etching stop film 160. In addition, a sidewall of the etching stop film 160 may be connected to an outer sidewall of the gate capping film 145. Alternatively, the etching stop film 160 may also be disposed on the sidewall of the gate capping film 145.

The etching stop film 160 may include a material having an etching selectivity with respect to a first interlayer insulating film 180 to be described later. The etching stop film 160 may include a nitride-based insulating material. For example, the etching stop film 160 may include at least one of silicon nitride (SIN), silicon oxynitride (SiON), silicon oxycarbonitride (SiOCN), silicon boron nitride (SiBN), silicon oxyboron nitride (SiOBN), and a combination thereof.

A first interlayer insulating film 180 may be disposed on the etching stop film 160. The first interlayer insulating film 180 may be formed on the field insulating film 105. The first interlayer insulating film 180 may be disposed on the source/drain pattern 150. The first interlayer insulating film 180 may not cover the upper surface of the gate capping film 145. For example, an upper surface of the first interlayer insulating film 180 may be on the same plane as the upper surface of the gate capping film 145.

The first interlayer insulating film 180 may include, for example, at least one of silicon oxide, silicon nitride, silicon oxynitride, and a low-k material. The low-k material may include, for example, fluorinated tetraethylorthosilicate (FTEOS), hydrogen silsesquioxane (HSQ), bis-benzocyclobutene (BCB), tetramethylorthosilicate (TMOS), octamethylcyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazene (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

A source/drain contact 170 may be disposed on the source/drain pattern 150. The source/drain contact 170 may be connected to the source/drain pattern 150. The source/drain contact 170 may penetrate through the first interlayer insulating film 180 and the etching stop film 160 and be connected to the source/drain pattern 150.

It is illustrated that the source/drain contact 170 is a single film, but this is only for convenience of explanation and the present disclosure is not limited thereto. The source/drain contact 170 may include, for example, at least one of a metal, a metal alloy, conductive metal nitride, conductive metal carbide, conductive metal oxide, conductive metal carbonitride, and a two-dimensional (2D) material.

A second interlayer insulating film 185 may be disposed on the first interlayer insulating film 180. The second interlayer insulating film 185 may include, for example, at least one of silicon oxide, silicon nitride, silicon oxynitride, and a low-k material.

Although not illustrated, an etching stop film having an etch selectivity with respect to the second interlayer insulating film 185 may be further disposed between the first interlayer insulating film 180 and the second interlayer insulating film 185.

A wiring structure 190 may be disposed in the second interlayer insulating film 185. The wiring structure 190 may be connected to the source/drain contact 170. The wiring structure 190 may include a wiring line 192 and a wiring via 191.

It is illustrated that the wiring line 192 and the wiring via 191 are separated from each other, but this is only for convenience of explanation, and the present disclosure is not limited thereto. That is, as an example, after the wiring via 191 is formed, the wiring line 192 may be formed. As another example, the wiring via 191 and the wiring line 192 may be formed at the same time.

It is illustrated that each of the wiring line 192 and the wiring via 191 is a single film, but this is only for convenience of explanation, and the present disclosure is not limited thereto. Each of the wiring line 192 and the wiring via 191 may include, for example, at least one of a metal, a metal alloy, conductive metal nitride, conductive metal carbide, conductive metal oxide, conductive metal carbonitride, and a two-dimensional (2D) material.

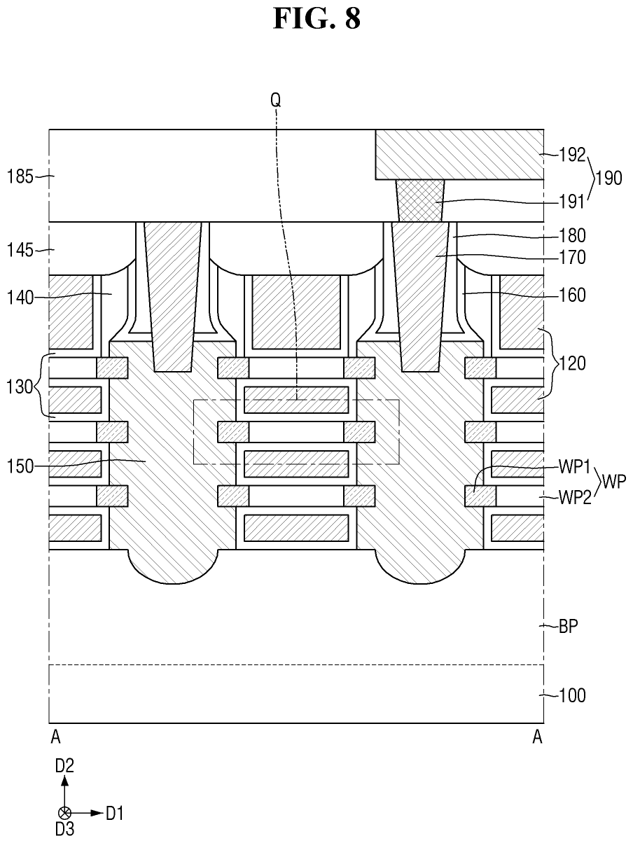

Hereinafter, a semiconductor device according to some other implementations will be described with reference to FIGS. 8 to 12. FIGS. 8 to 12 are views for describing a semiconductor device according to some other implementations. For the convenience of explanation, the contents overlapping those described with reference to FIGS. 1 to 7 will be omitted.

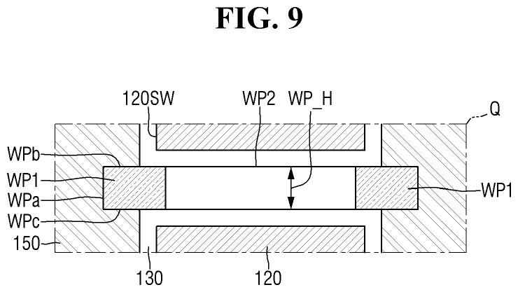

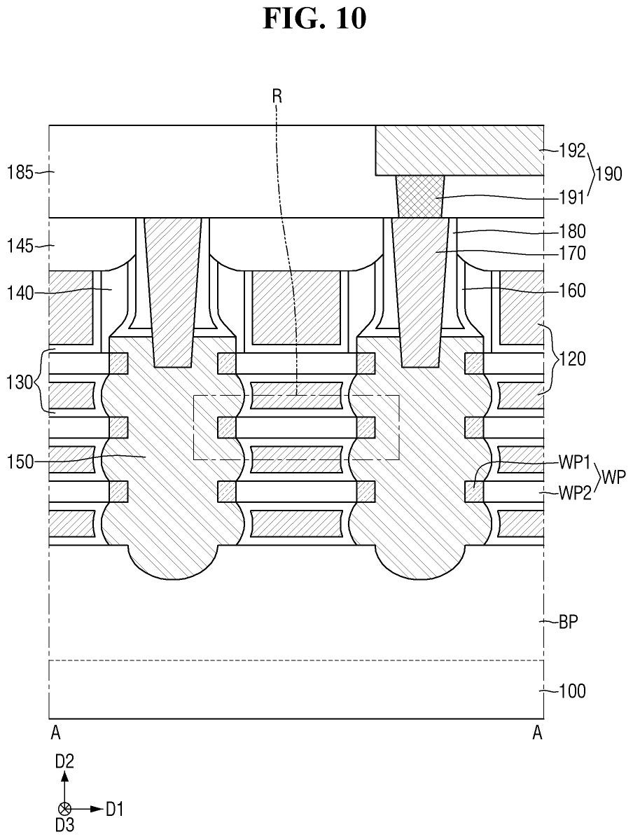

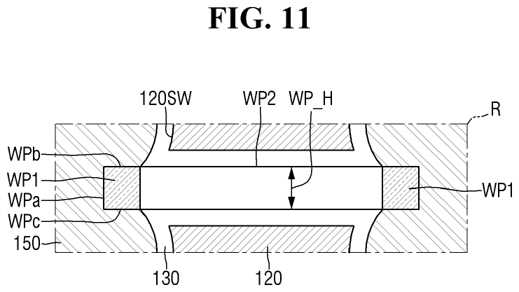

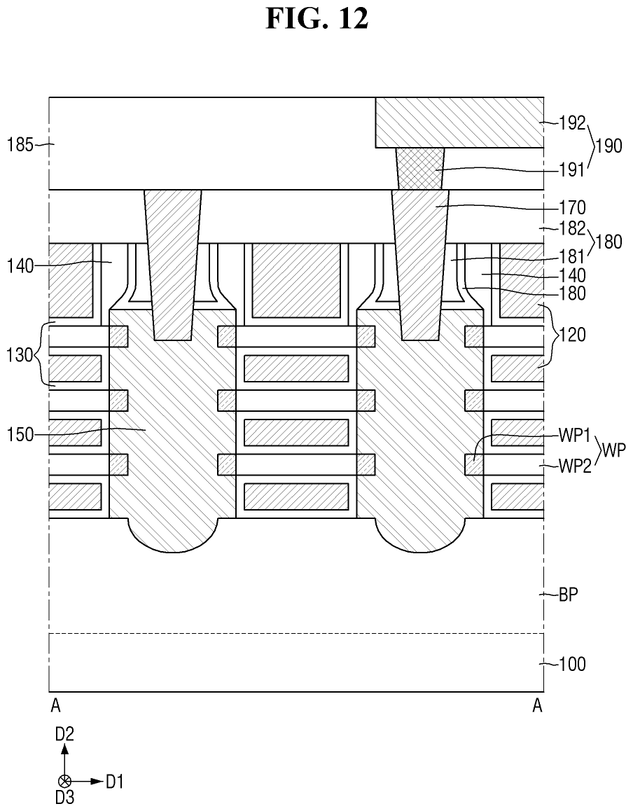

For reference, FIG. 8 may be a cross-sectional view taken along line A-A of FIG. 1, and FIG. 9 may be an enlarged view of area Q of FIG. 8. For reference, FIG. 10 may be a cross-sectional view taken along line A-A of FIG. 1, and FIG. 11 may be an enlarged view of area R of FIG. 9. FIG. 12 is a cross-sectional view taken along line A-A of FIG. 1.

Referring to FIGS. 8 and 9, at least a portion of the first areas WP1 of the wire pattern WP may overlap the gate electrode 120 in the second direction D2. A portion of the first areas WP1 may not be in contact with the source/drain pattern 150.

In the process of forming the first areas WP1, the first areas WP1 may be formed to be deeper. The first areas WP1 may be formed through a plasma treatment, electron beam irradiation, and/or an immersion process. In such a process, when the first areas WP1 is deeply formed, at least a portion of the first areas WP1 may overlap the gate electrode 120 in the second direction D2.

Referring to FIGS. 10 and 11, a sidewall of the source/drain pattern 150 in contact with the gate insulating film 130 may have a wavy shape.

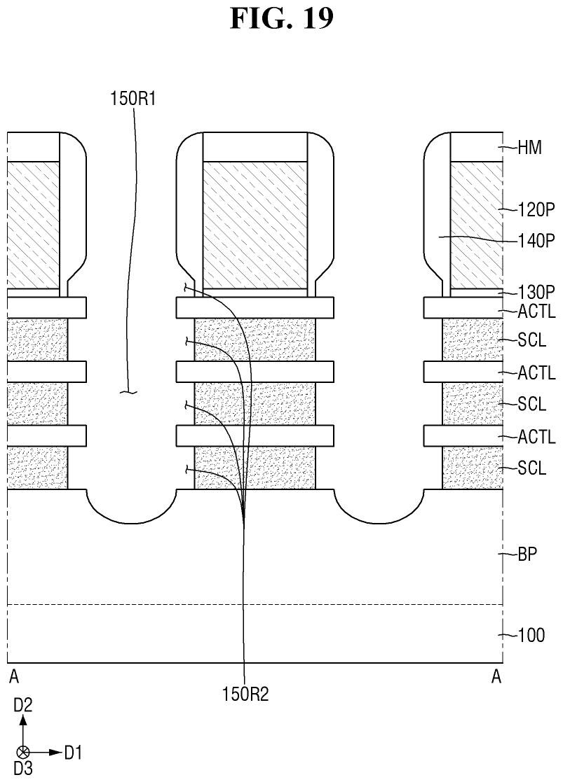

In the process of forming the first areas WP1, a portion of a sacrificial film (SCL in FIG. 19) may be selectively removed. As the sacrificial film is removed, a sidewall of the sacrificial film may have a convex shape. As the source/drain pattern 150 fills a space from which the sacrificial film is removed, the sidewall of the source/drain pattern 150 may have a wavy shape.

For example, the sidewall of the source/drain pattern 150 in contact with the gate insulating film 130 may be convex toward the gate electrode 120. A width of the gate electrode 120 overlapping the source/drain pattern 150 in the first direction DI in the first direction DI may gradually decrease as a distance from the wire pattern WP increases.

Referring to FIG. 12, the gate capping film 145 may not be disposed. The first interlayer insulating film 180 includes a first portion 181 and a second portion 182.

The first portion 181 of the first interlayer insulating film 180 may be disposed on the etching stop film 160. The first portion 181 of the first interlayer insulating film 180 may surround a portion of the source/drain contact 170. An upper surface of the first portion 181 of the first interlayer insulating film 180 may be on the same plane as an upper surface of the gate electrode 120.

The second portion 182 of the first interlayer insulating film 180 may be disposed on the first portion 181 of the first interlayer insulating film 180. The second portion 182 of the first interlayer insulating film 180 may be disposed on the gate electrode 120. The etching stop film 160 is not disposed within the second portion 182 of the first interlayer insulating film 180. An upper surface of the second portion 182 of the first interlayer insulating film 180 may be on the same plane as an upper surface of the source/drain contact 170.

The second portion 182 of the first interlayer insulating film 180 and the first portion 181 of the first interlayer insulating film 180 may be formed of the same material. For example, both the second portion 182 of the first interlayer insulating film 180 and the first portion 181 of the first interlayer insulating film 180 may include at least one of silicon oxide, silicon nitride, silicon oxynitride, and a low-k material. However, the technical spirit of the present disclosure is not limited thereto.

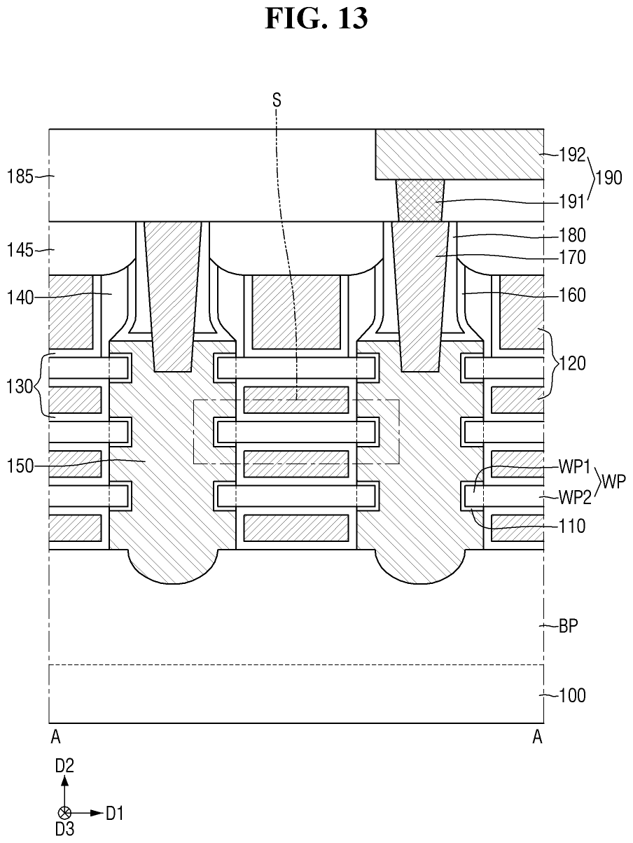

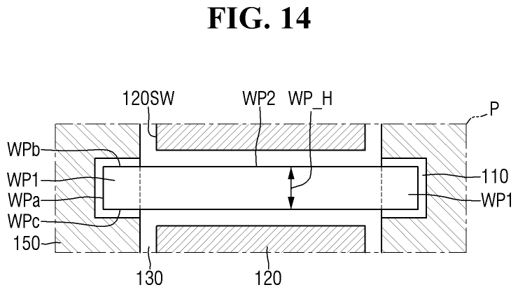

Hereinafter, a semiconductor device according to some still other implementations will be described with reference to FIGS. 13 to 15. For the convenience of explanation, the contents overlapping those described with reference to FIGS. 1 to 7 will be briefly described or omitted. FIG. 13 is a view for describing a semiconductor device according to some still other implementations. FIG. 14 is an enlarged view of area S of FIG. 13.

Referring to FIGS. 13 and 14, a semiconductor device according to some implementations further includes a barrier pattern 110.

The barrier pattern 110 may be interposed between the source/drain pattern 150 and the wire pattern WP. Specifically, the barrier pattern 110 may be interposed between the source/drain pattern 150 and the first areas WP1 of the wire pattern WP. The barrier pattern 110 may completely surround the protruding first areas WP1 of the wire pattern WP.

In FIG. 14, the barrier pattern 110 may be in contact with the first surface WPa, the second surface WPb, and the third surface WPc of the first areas WP1. The barrier pattern 110 may be interposed between the first surface WPa of the first areas WP1 and the source/drain pattern 150, between the second surface WPb of the first areas WP1 and the source/drain pattern 150, and between the third surface WPc of the first areas WP1 and the source/drain pattern 150.

As an example, the barrier pattern 110 may include a transition metal. Specifically, the transition metal included in the barrier pattern 110 may be a Group 4 transition metal. For example, the barrier pattern 110 may include titanium (Ti), zirconium (Zr), and hafnium (Hf), but is not limited thereto.

As another example, the barrier pattern 110 may include a TMD material. The TMD material has been described above, and therefore will be omitted below.

In some implementations, the barrier pattern 110 may be used as a buffer layer for protecting the wire pattern WP when a subsequent process is performed after forming the barrier pattern 110. For example, the barrier pattern 110 may protect the wire pattern WP when the source/drain pattern 150 is formed.

In FIG. 13, the phase of the first areas WP1 and the phase of the second area WP2 of the wire pattern WP may be the same. For example, both the phase of the first areas WP1 and the phase of the second area WP2 may be a 2H phase. Even if the first areas WP1 has the 2H phase, since a portion in contact with the source/drain pattern 150 is the barrier pattern 110, a resistance between the source/drain pattern 150 and the wire pattern WP may be reduced.

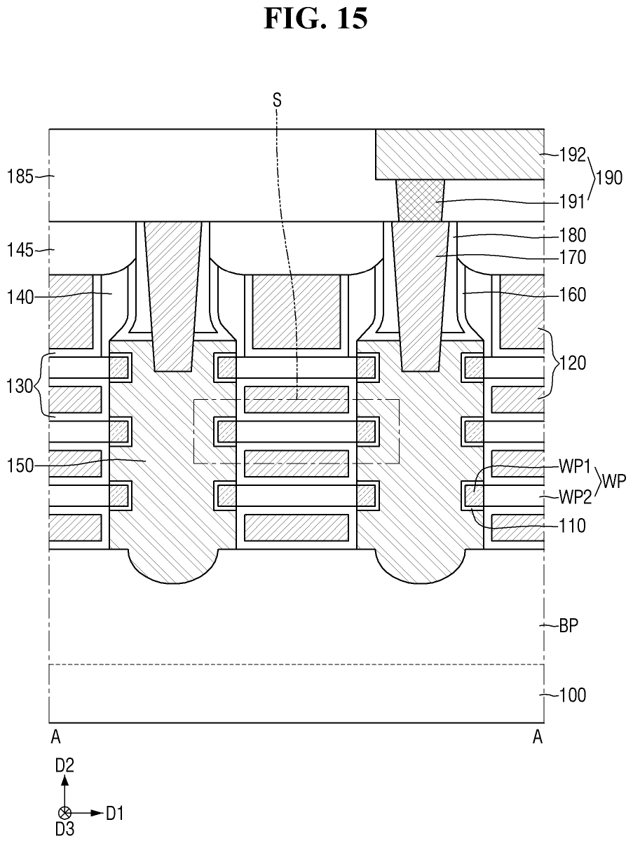

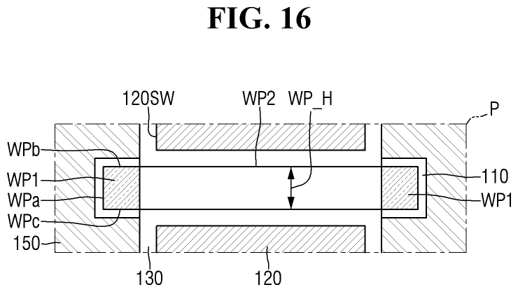

FIGS. 15 and 16 are views for describing a semiconductor device according to some still other implementations. For reference, FIG. 15 may be a cross-sectional view taken along line A-A of FIG. 1, and FIG. 16 may be an enlarged view of area T of FIG. 15.

Referring to FIGS. 15 and 16, the phase of the first areas WP1 and the phase of the second area WP2 of the wire pattern WP may be different from each other. For example, the phase of the first areas WP1 may be a 1T phase, and the phase of the second area WP2 may be a 2H phase. The barrier pattern 110 may be disposed on a transition metal dichalcogenide material having a 1T phase.

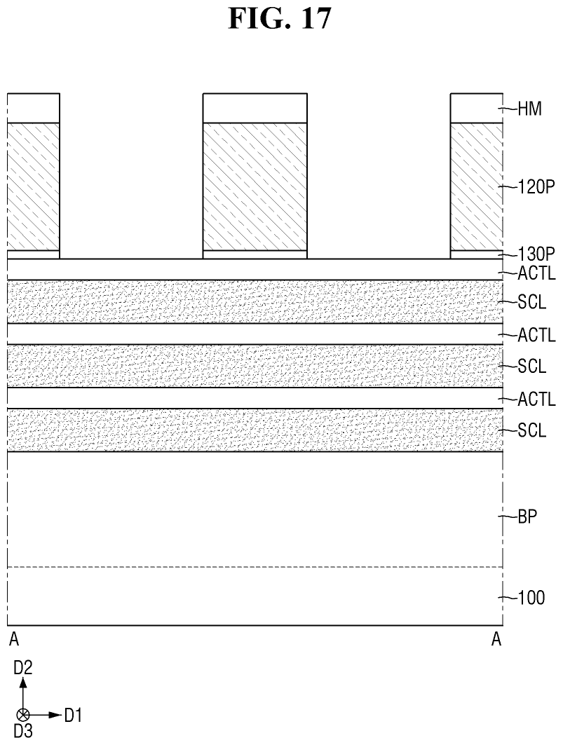

Hereinafter, a method of manufacturing a semiconductor device according to some implementations will be described with reference to FIGS. 17 to 27. Hereinafter, a method of manufacturing a semiconductor device according to some implementations will be described with reference to FIGS. 17 to 23.

FIGS. 17 to 23 are intermediate step views for describing a method of manufacturing a semiconductor device having the cross section of FIG. 2.

Referring to FIG. 17, a substrate 100 is provided. A lower pattern BP may be formed on the substrate 100.

A sacrificial film SCL and an active film ACTL may be alternately stacked on the lower pattern BP. For example, the sacrificial film SCL may be first formed on the lower pattern BP. The active film ACTL may be formed on the sacrificial film SCL. The sacrificial film SCL may be formed again on the active film ACTL. It is illustrated in FIG. 17 that three sacrificial films SCL and three active films ACTL are alternately stacked, but the technical spirit of the present disclosure is not limited thereto.

The sacrificial film SCL may include an insulating material. For example, the sacrificial film SCL may include an oxide-based insulating material. As an example, the sacrificial film SCL may include silicon oxide, and as another example, the sacrificial film SCL may include aluminum oxide (AlO), but the technical spirit of the present disclosure is not limited thereto.

The active film ACTL may include a TMD material. For example, the transition metal dichalcogenide material may have the form of MX₂. The M may be a transition metal, and the X may be a chalcogen element. That is, the transition metal dichalcogenide material may be a combination of one transition metal and two chalcogen elements.

The active film ACTL may have a combination of transition metals including scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), ruthenium (Ru), rhodium (Rh), palladium (Pd), cadmium (Cd), hafnium (Hf), tantalum (Ta), tungsten (W), and iridium (Ir), and calogen elements including sulfur(S), selenium (Se), and tellurium (Te). As an example, the active film ACTL may include at least one of WS₂, WSe₂, WTe₂, ZrS₂, ZrSe₂, ZrTe₂, MoS₂, MoSe₂, and MoTe₂, but is not limited thereto.

Subsequently, a dummy gate insulating film 130p, a dummy gate electrode 120p, and a hard mask film HM may be formed on the active layer ACTL disposed at the uppermost portion. The dummy gate insulating film 130p may include, for example, silicon oxide, but is not limited thereto. The dummy gate electrode 120p may include, for example, polysilicon, but is not limited thereto. The hard mask film HM may include, for example, silicon nitride, but is not limited thereto.

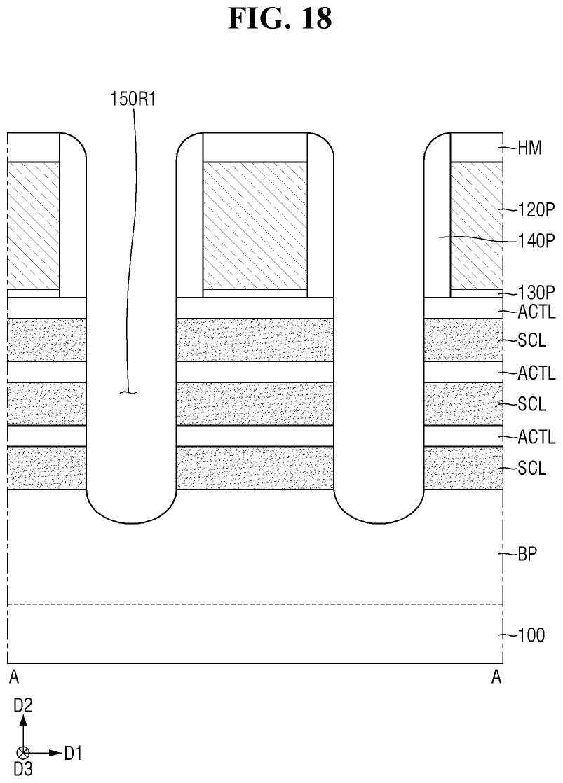

Referring to FIG. 18, a pre-gate spacer 140p may be formed on a sidewall of the dummy gate electrode 120p.

The sacrificial film SCL and the active film ACTL may be etched using the dummy gate electrode 120p as a mask. A first source/drain recess 150R1 may be formed by etching the sacrificial film SCL and the active film ACTL.

As an example, while the pre-gate spacer 140p is formed, the first source/drain recess 150R1 may be formed. As another example, after the pre-gate spacer 140p is formed, the first source/drain recess 150R1 may be formed.

A portion of the first source/drain recess 150R1 may be formed in the lower pattern BP. A bottom surface of the first source/drain recess 150R1 may be defined by the lower pattern BP.

Referring to FIG. 19, a second source/drain recess 150R2 may be formed by etching a portion of the sacrificial film SCL and a portion of the pre-gate spacer 140p.

For example, a portion of the sacrificial film SCL and a portion of the pre-gate spacer 140p may be removed through a wet etching process. The sacrificial film SCL and the active film ATCL have an etch selectivity with respect to each other. Therefore, the active film ATCL may not be removed while the sacrificial film SCL is removed. Likewise, the pre-gate spacer 140p and the active film ATCL have an etch selectivity with respect to each other. Therefore, the active film ATCL may not be removed while the pre-gate spacer 140p is removed.

In some implementations, the pre-gate spacer 140p and the active film ATCL may be formed of the same material. In this case, when the active film ATCL is removed, the pre-gate spacer 140p may also be removed.

As portions of the sacrificial film SCL and the pre-gate spacer 140p are removed, at least a portion of the active film ACTL may protrude from the sidewall of the sacrificial film SCL in the first direction D1.

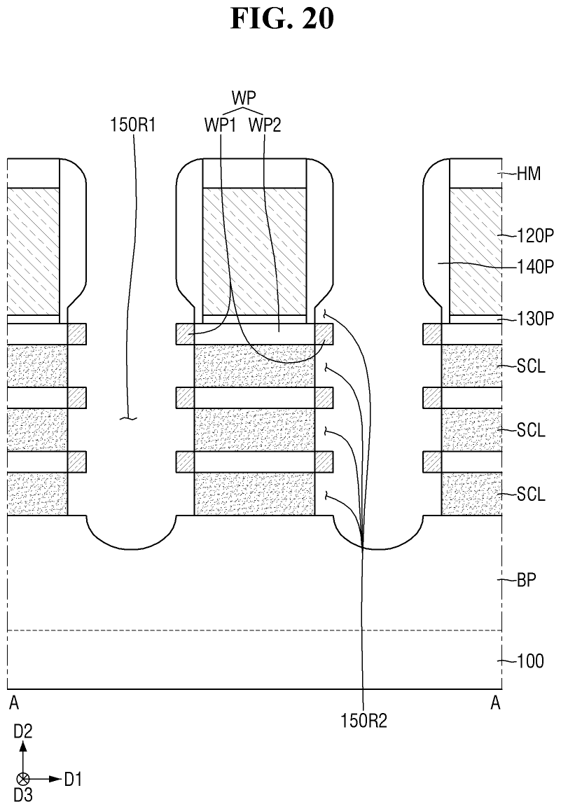

Referring to FIG. 20, a wire pattern WP may be formed. The wire pattern WP includes a pair of first areas WP1 and a second area WP2.

First, the first areas WP1 may be formed through a phase change process. The phase change process may be a plasma treatment, an electron beam irradiation, and/or an immersion process.

When the phase change process is performed, a phase of the protruding portion of the active film ACTL may be changed. For example, before the phase change process is performed, the phase of the protruding portion of the active film ACTL may be a 2H phase. After the phase change process is performed, the phase of the protruding portion of the active film ACTL may be changed to a 1T phase. A phase of the active film ACTL exposed by the first source/drain recess 150R1 and the second source/drain recess 150R2 may be changed. A phase of the unexposed active film ACTL may be a 2H phase.

Accordingly, the first areas WP1 may have a 1T phase, and the second area WP2 may have a 2H phase.

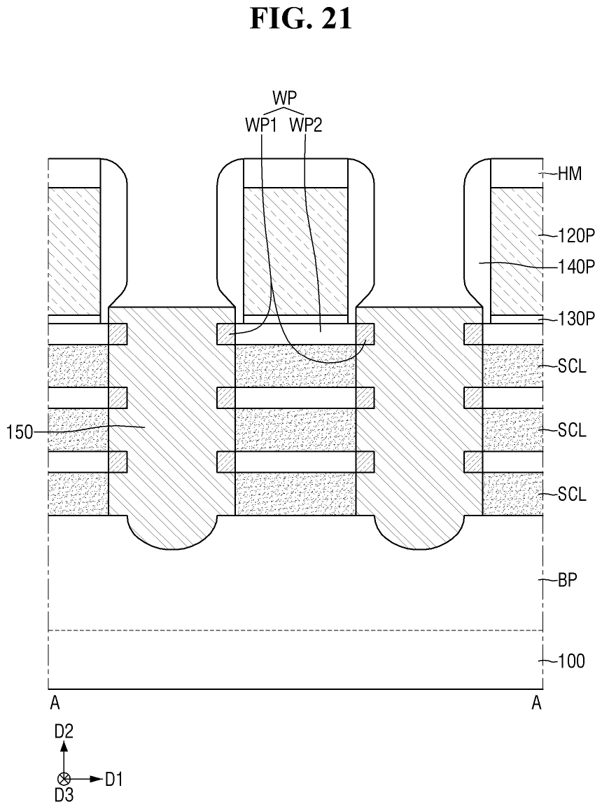

Referring to FIG. 21, a source/drain pattern 150 may be formed. The source/drain pattern 150 may fill the first source/drain recess 150R1 and the second source/drain recess 150R2. The source/drain pattern 150 may be connected to the wire pattern WP. The source/drain pattern 150 may surround the first areas WP1 of the wire pattern WP. The source/drain pattern 150 may be in contact with the first areas WP1 of the wire pattern WP.

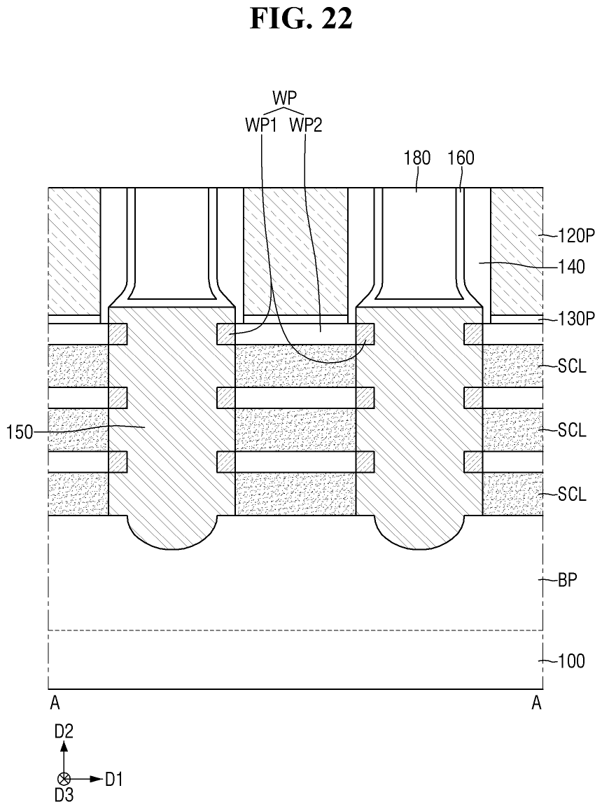

Referring to FIG. 22, an etching stop film 160 and a first interlayer insulating film 180 are sequentially formed on the source/drain pattern 150.

Subsequently, an upper surface of the dummy gate electrode 120p is exposed by removing a portion of the first interlayer insulating film 180, a portion of the etching stop film 160, and the hard mask film HM. While the upper surface of the dummy gate electrode 120P is exposed, first gate spacers 140 may be formed.

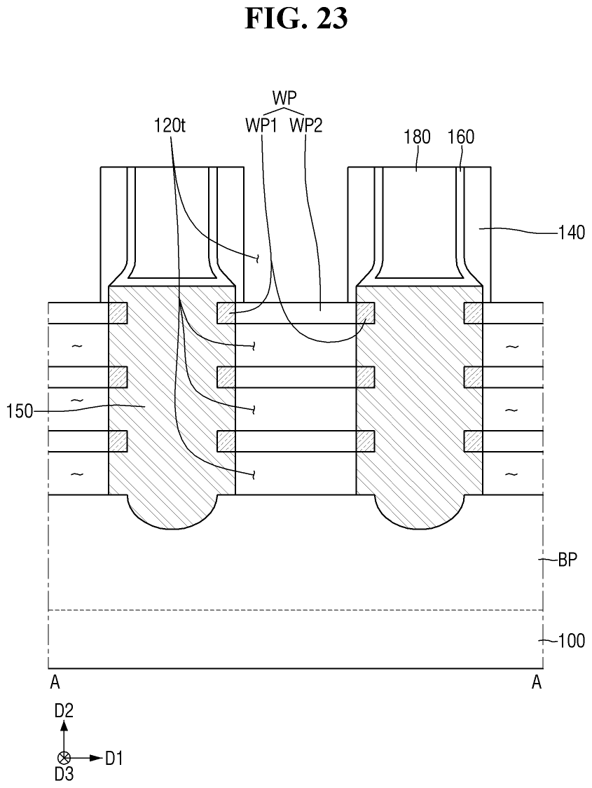

Referring to FIG. 23, a gate trench 120t may be formed between the first gate spacers 140 by removing the sacrificial film SCL. When the sacrificial film SCL is removed, a portion of the source/drain pattern 150 may be exposed.

Subsequently, referring to FIG. 2, a first gate insulating film 130 and a first gate electrode 120 may be formed in the gate trench 120t. In addition, a first gate capping film 145 may be formed.

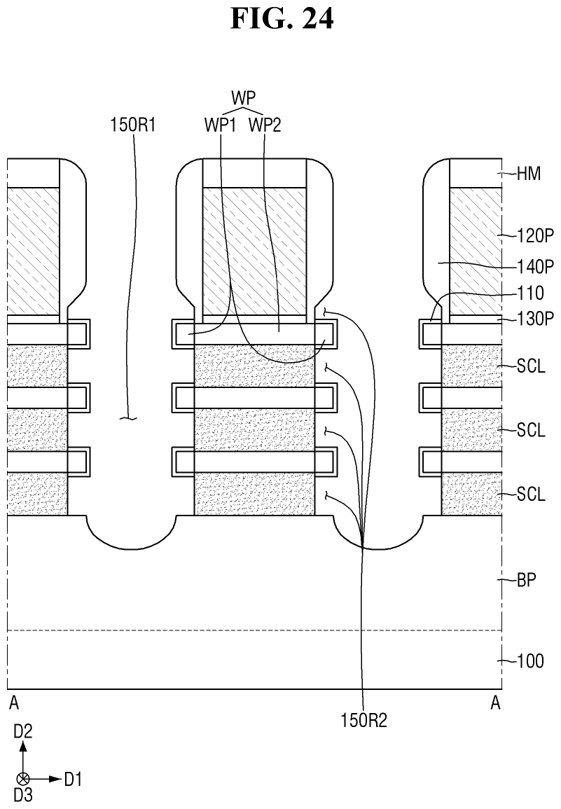

FIGS. 24 to 27 are intermediate step views for describing a method of manufacturing a semiconductor device having the cross section of FIG. 13. For reference, a process of forming the second source/drain recess 150R2 may be the same as the method of manufacturing the semiconductor device having the cross section of FIG. 2.

Referring to FIG. 24, a barrier pattern 110 may be formed on the first areas WP1 of the wire pattern WP. The barrier pattern 110 may be selectively formed on a surface of the wire pattern WP. The barrier pattern 110 may include a Group 4 transition metal. The barrier pattern 110 may be selectively deposited only on a transition metal dichalcogenide material without being deposited on an insulating material under a specific temperature condition.

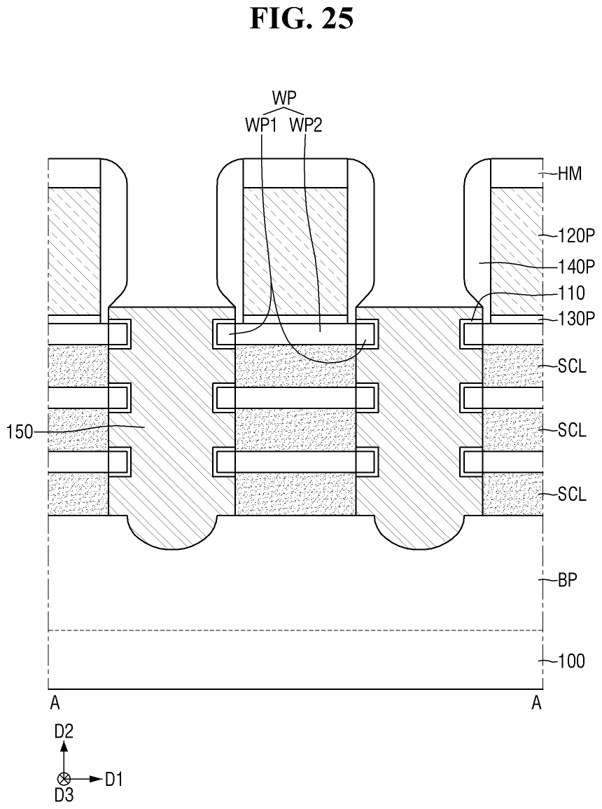

Referring to FIG. 25, a source/drain pattern 150 may be formed. The source/drain pattern 150 may fill the first source/drain recess 150R1 and the second source/drain recess 150R2.

The source/drain pattern 150 may be connected to the wire pattern WP. The source/drain pattern 150 may surround the barrier pattern 110. The source/drain pattern 150 may be in contact with the barrier pattern 110.

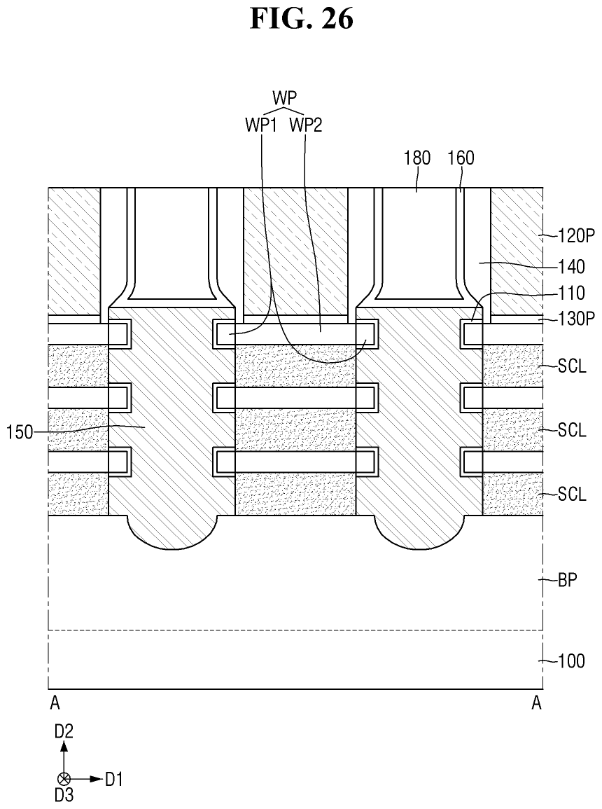

Referring to FIG. 26, an etching stop film 160 and a first interlayer insulating film 180 are sequentially formed on the source/drain pattern 150.

Subsequently, an upper surface of the dummy gate electrode 120p is exposed by removing a portion of the first interlayer insulating film 180, a portion of the etching stop film 160, and the hard mask film HM. While the upper surface of the dummy gate electrode 120P is exposed, first gate spacers 140 may be formed.

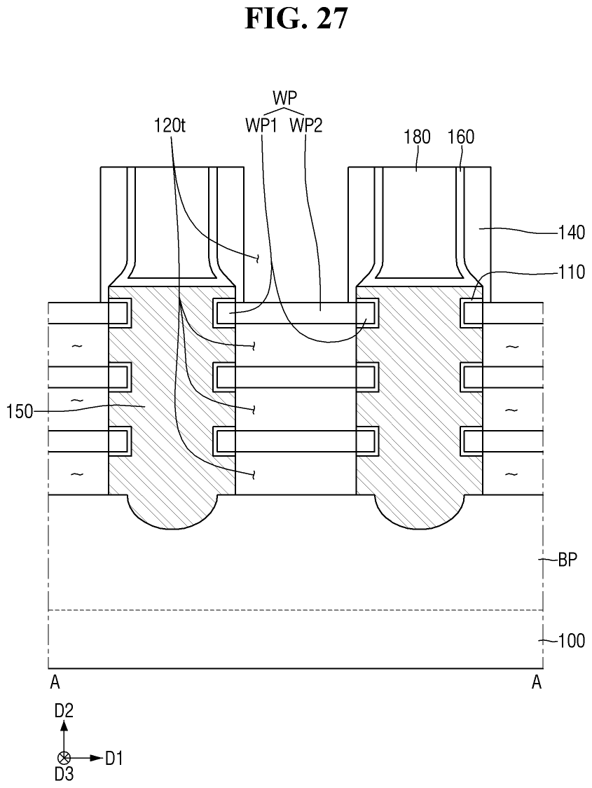

Referring to FIG. 27, a gate trench 120t may be formed between the first gate spacers 140 by removing the sacrificial film SCL. When the sacrificial film SCL is removed, a portion of the source/drain pattern 150 may be exposed.

Subsequently, referring to FIG. 2, a first gate insulating film 130 and a first gate electrode 120 may be formed in the gate trench 120t. In addition, a first gate capping film 145 may be formed.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

In concluding the detailed description, those skilled in the art will appreciate that many variations and modifications may be made to the implementations without substantially departing from the principles of the present disclosure. Therefore, the disclosed implementations of the disclosure are used in a generic and descriptive sense only and not for purposes of limitation.

What is claimed is:

1. A semiconductor device comprising:
a lower pattern extending in a first direction;
a plurality of wire patterns disposed on the lower pattern and spaced apart from the lower pattern in a second direction; and
a gate electrode surrounding the plurality of wire patterns, disposed on the lower pattern, and extending in a third direction,
wherein each of the plurality of wire patterns includes a transition metal dichalcogenide (TMD) material,
wherein each of the plurality of wire patterns includes:
a pair of first areas protruding from sidewalls of the gate electrode in the first direction, and
a second area between the first areas, and
wherein a phase of each first area of the pair is different from a phase of the second area.

2. The semiconductor device of claim 1, further comprising:
a source/drain pattern disposed on the sidewalls of the gate electrode and connected to the plurality of wire patterns,
wherein the source/drain pattern includes a semimetal material.

3. The semiconductor device of claim 2, wherein the source/drain pattern surrounds the pair of first areas.

4. The semiconductor device of claim 2, wherein the source/drain pattern has a single layer.

5. The semiconductor device of claim 1, wherein a thickness of each of the plurality of wire patterns in the second direction is 1 nm or less.

6. The semiconductor device of claim 1, wherein a molecular structure of the pair of first areas has a first angle between i) a first connection between a transition metal and a first chalcogen element and ii) a second connection between the transition metal and a second chalcogen element adjacent to the first chalcogen element in a plan view of the molecular structure of the pair of first areas,
wherein a molecular structure of the second area has a second angle between iii) a third connection between the transition metal and a third chalcogen element and ii) a fourth connection between the transition metal and a fourth chalcogen element adjacent to the third chalcogen element in a plan view of the molecular structure of the second area, and
wherein the first angle is less than the second angle.

7. The semiconductor device of claim 1, wherein in a molecular structure of the pair of first areas, six chalcogen elements are disposed around one transition metal in a plan view of the molecular structure of the pair of first areas, and
wherein in a molecular structure of the second area, three chalcogen elements are disposed around one transition metal in a plan view of the molecular structure of the second area.

8. The semiconductor device of claim 1, further comprising:
a barrier pattern surrounding the pair of first areas,
wherein a transition metal included in the barrier pattern is a Group 4 transition metal.

9. A semiconductor device comprising:
a lower pattern extending in a first direction;
a plurality of wire patterns disposed on the lower pattern and spaced apart from the lower pattern in a second direction;
a plurality of gate electrodes surrounding the plurality of wire patterns, disposed on the lower pattern, extending in a third direction, and spaced apart from each other in the first direction; and
a source/drain pattern connected to the plurality of wire patterns between the plurality of gate electrodes,
wherein each of the plurality of wire patterns includes a transition metal dichalcogenide (TMD) material,
wherein each of the plurality of wire patterns includes:
a first area surrounded by the source/drain pattern, and
a second area that is not in contact with the source/drain pattern,
wherein a molecular structure of the first area has a first angle between i) a first connection between a transition metal and a first chalcogen element and ii) a second connection between the transition metal and a second chalcogen element adjacent to the first chalcogen element in a plan view of the molecular structure of the pair of first areas,
wherein a molecular structure of the second area has a second angle between iii) a third connection between the transition metal and a third chalcogen element and ii) a fourth connection between the transition metal and a fourth chalcogen element adjacent to the third chalcogen element in a plan view of the molecular structure of the second area, and
wherein the first angle is less than the second angle.

10. The semiconductor device of claim 9, wherein the source/drain pattern includes a semimetal material.

11. The semiconductor device of claim 9, wherein in the molecular structure of the first area, six chalcogen elements are disposed around one transition metal a plan view of the molecular structure of the pair of first areas, and
wherein in the molecular structure of the second area, three chalcogen elements are disposed around one transition metal in a plan view of the molecular structure of the second area.

12. The semiconductor device of claim 9, wherein a phase of the first area is different from a phase of the second area.

13. The semiconductor device of claim 9, wherein a thickness of each of the plurality of wire patterns in the second direction is 1 nm or less.

14. The semiconductor device of claim 9, wherein the source/drain pattern has a single layer.

15. The semiconductor device of claim 9, further comprising:
a barrier pattern disposed between the first area and the source/drain pattern,
wherein a transition metal included in the barrier pattern includes a Group 4 transition metal.

16. A semiconductor device comprising:
a lower pattern extending in a first direction;
a plurality of wire patterns disposed on the lower pattern and spaced apart from the lower pattern in a second direction, wherein each wire pattern of the plurality of wire patterns includes a pair of first areas spaced apart from each other in the first direction and a second area between the pair of first areas;
a plurality of gate electrodes surrounding second areas of the plurality of wire patterns, disposed on the lower pattern, extending in a third direction, and spaced apart from each other in the first direction;
a source/drain pattern connected to the plurality of wire patterns between the plurality of gate electrodes that are adjacent to each other; and
a barrier pattern interposed between the pair of first areas and the source/drain pattern,
wherein each of the plurality of wire patterns includes a transition metal dichalcogenide (TMD) material, and
wherein a transition metal included in the barrier pattern is a Group 4 transition metal.

17. The semiconductor device of claim 16, wherein the source/drain pattern includes a semimetal material.

18. The semiconductor device of claim 16, wherein a thickness of each of the plurality of wire patterns in the second direction is 1 nm or less.

19. The semiconductor device of claim 16, wherein a molecular structure of the pair of first areas has a first angle between i) a first connection between a transition metal and a first chalcogen element and ii) a second connection between the transition metal and a second chalcogen element adjacent to the first chalcogen element in a plan view of the molecular structure of the pair of first areas,
wherein a molecular structure of the second area has a second angle between iii) a third connection between the transition metal and a third chalcogen element and ii) a fourth connection between the transition metal and a fourth chalcogen element adjacent to the third chalcogen element in a plan view of the molecular structure of the second area, and
wherein the first angle is less than the second angle.

20. The semiconductor device of claim 16, wherein a phase of each first area of the pair is different from a phase of the second area.
